(19) United States
(12) Patent Application Publication
(10) Pub. No.: US 2005/0282384 A1
(43) Pub. Date: Dec. 22, 2005

(54) Method for forming protective film and electroless plating bath

(76) Inventors: Hidemi Nawafune, Osaka (JP); Kensuke Akamatsu, Kyoto (JP); Katashige Matsuda, Osaka (JP); Akira Fukunaga, Tokyo (JP); Ryoichi Kimizuka, Kanagawa-ken (JP); Moriji Matsumoto, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 10/868,824

(22) Filed: Jun. 17, 2004

(51) Int. Cl. H01L 21/44; H01L 21/31; H01L 21/469

(52) U.S. Cl. 438/678

(57) ABSTRACT

The present invention provides a method for forming a protective film selectively on metal interconnects, such as copper interconnects, of a substrate having an embedded interconnect structure, without causing the problem of contamination of the interconnects with an-alkali metal. The method for forming a protective film according to the present invention comprises: providing a substrate having embedded interconnects formed in a surface of the substrate; and bringing the surface of the substrate into contact with an electroless plating bath, thereby forming a protective film having a film thickness of 0.1 to 500 nm selectively on the exposed surface of the embedded interconnects; wherein the electroless plating bath contains cobalt ions, phosphinate ions and a complexing agent, uses cobalt phosphinate as a main supply source of the cobalt ions and the phosphinate ions, and does not substantially contain alkali metal ions.

### BACKGROUND OF THE INVENTION

1. Field of the Invention:

The present invention relates to a method for forming a protective film and to an electroless plating bath, and more particularly to a method for forming a protective film, such as a magnetic film or the like, on the exposed surfaces of embedded interconnects of a conductive material (interconnect material), such as copper or silver, embedded in interconnect recesses provided in a surface of a substrate such as a semiconduct or wafer, and to an electroless plating bath for use in the method.

2. Description of the Related Art:

As a process for forming interconnects in a semiconductor device, the so-called “damascene process”, which comprises embedding a metal (interconnect material) into interconnect recesses, such as interconnect trenches and via holes, is coming into practical use. According to this process, aluminum or, more recently a metal such as copper or silver, is embedded into interconnect trenches and via holes previously formed in an interlevel dielectric layer. Thereafter, extra metal is removed by chemical mechanical polishing (CMP) so as to flatten a surface of the substrate.

In the case of interconnects formed by such a process, for example, copper interconnects used copper as an interconnect material, the embedded interconnects of copper has exposed surfaces after the flattening processing. Therefore, when an additional embedded interconnect structure is formed in an insulating film (interlevel dielectric layer) deposited on such a surface, it has conventionally been conducted to form a protective film of SiN or the like on the entire surface of the substrate, thereby protecting a circuit-formed region where interconnects is previously formed and preventing the contamination with an etchant or the like

However, the provision of a protective film of SiN or the like on the entire surface of a substrate increases the dielectric constant of the interlevel dielectric layer, thus inducing delayed interconnects. In view of this, it has been proposed to selectively cover and protect the surfaces of the exposed interconnects with a plated film of metal, such as cobalt exhibiting a good adhesion to an interconnect material such as copper or, specially a cobalt alloy having a low resistivity, which is obtained by electroless plating.

An alkali metal salt, such as sodium phosphinate (sodium hypophosphite), is generally used as a reducing agent in an electroless plating bath for use in the selective formation of a protective film of a cobalt alloy or the like by electroless plating. When selectively forming a plated film (protective film) on metal interconnects by electroless plating using such an electrolytic plating bath, alkali metal ions are taken in the plated film. The contamination of the metal interconnects with the alkali metal, such as sodium, can adversely affect the electrical properties of the substrate.

### SUMAMRY OF THE INVENTION

The present invention has been made in view of the above situation in the related art. It is therefore an object of the present invention to provide a method for forming a protective film selectively on metal interconnects, such as copper interconnects, of a substrate having an embedded interconnect structure, without causing the problem of contamination of the interconnects with an alkali metal, and to provide an electroless plating bath for use in the method.

In order to achieve the above problem, the present invention provides a method for forming a protective film comprising: providing a substrate having embedded interconnects formed in a surface of the substrate; and bringing the surface of the substrate into contact with an electroless plating bath, thereby forming a protective film having a film thickness of 0.1 to 500 nm selectively on the exposed surfaces of the embedded interconnects; wherein the electroless plating bath contains cobalt ions, phosphinate ions and a complexing agent, uses cobalt phosphinate as a main supply source of the cobalt ions and the phosphinate ions, and does not substantially contain alkali metal ions.

According to the present invention, cobalt phosphinate is used as a main supply source of cobalt ions and phosphinate ions in the electroless plating bath, and therefore alkali metal ions, such as sodium ions, are not present in the electroless plating bath. This makes it possible to form a protective film selectively on the surfaces of interconnects while preventing contamination of the interconnects with an alkali metal. Furthermore, there is no formation of a by-product, such as sodium sulfate, even when plating is continued while replenishing the components of the electroless plating bath. Accordingly, protective films of constant quality can be formed stably over a long period of time.

The film thickness of the protective film is generally 0.1 to 500 nm, preferably about 1 to 200 nm, more preferably about 10 to 100 nm.

The deposition rate of the protective film is preferably 0.1 to 38 nm/min.

Since the deposition rate is directly linked to the productivity, it cannot be made very low. Too high a deposition rate, on the other hand, cannot ensure the uniformity and the reproducibility of plating. The film thickness of the protective film for protecting interconnects is generally 0.1 to 500 nm, and it is desirable to employ a deposition rate of 0.1 to 38 nm/min to obtain such a film thickness. The deposition rate can be controlled both by the compositional conditions, such as pH, of the plating bath, and by the reaction conditions, such as the reaction temperature.

Preferably, the substrate after the formation of the protective film is subjected to heat treatment.

The heat treatment of the substrate can modify the protective film (plated film) formed on the exposed surfaces of interconnects so as to improve the barrier properties of the protective film and increase the adhesion of the protective film to the interconnects. By carrying out heat treatment immediately after the formation of the protective film, thermal deformation, etc. of the protective film (plated film) formed on the exposed surfaces of the interconnects can be minimized.

The heat treatment temperature is, for example, 120 to 450° C.

The temperature necessary for modification of the protective film is at least 120° C., also taking into account the practical processing time. Further, taking into account the heat resistance of materials constituting devices, the heat treatment temperature preferably should not exceed 450° C.

The present invention also provides another method for forming a protective film comprising: providing a substrate having embedded interconnects formed in a surface of the substrate; and bringing the surface of the substrate into contact with an electroless plating bath, thereby forming a protective film having a film thickness of 0.1 to 500 nm selectively on the exposed surfaces of the embedded interconnects; wherein the electroless plating bath contains cobalt ions, phosphinate ions, a complexing agent and a high-melting metal compound, uses cobalt phosphinate as a main supply source of the cobalt ions and the phosphinate ions, and does not substantially contain alkali metal ions.

The use of the electroless plating bath containing a high-melting metal compound allows the high-melting metal to be co-deposited and alloyed in the protective film (plated film), thereby enhancing the thermal stability of the protective film.

The high-melting metal contained in the high-melting metal compound is, for example, tungsten and/or molybdenum.

The present invention also provides an electroless plating bath comprising cobalt ions, phosphinate ions and a complexing agent and not substantially containing alkali metal ions, wherein the cobalt ions and the phosphinate ions are mainly derived from cobalt phosphinate obtained by adding cobalt hydroxide to hypophosphorous acid or by the double decomposition reaction between barium hypophosphite and cobalt sulfate.

### BRIEF DESCRIPTION OF THE DRAWINGS

FIGS. 1A through 1D are illustrate, a sequence of process steps, an example of forming copper interconnects protected with a proactive film;

FIG. 2 is a horizontal arrangement view of a substrate processing apparatus for use the formation of a protective film according to an embodiment of the present invention;

FIG. 3 is a process flow chart in the substrate processing apparatus shown in FIG. 2;

FIG. 4 is a front view of a pre-treatment unit at the time of substrate delivery;

FIG. 5 is a front view of the pre-treatment unit at the time of a chemical liquid process;

FIG. 6 is a front view of the pre-treatment unit at the time of rinsing;

FIG. 7 is a cross-sectional view showing a processing head of the pre-treatment unit at the time of substrate delivery;

FIG. 8 is an enlarged view of a portion A of FIG. 7;

FIG. 9 is a view of the pre-treatment unit when the substrate is fixed, which corresponds to FIG. 8;

FIG. 10 is a schematic diagram of the pre-treatment unit;

FIG. 11 is a cross-sectional view showing a substrate head of an electroless plating unit when a substrate is delivered;

FIG. 12 is an enlarged view of a portion B of FIG. 11;

FIG. 13 is a view of the substrate head of the electroless plating unit when the substrate is fixed, which corresponds to FIG. 12;

FIG. 14 is a view of the substrate head of the electroless plating unit at the time of a plating process, which corresponds to FIG. 12;

FIG. 15 is a front view showing, in a partially cutaway manner, a plating tank of the electroless plating unit when a plating tank cover is closed;

FIG. 16 is a cross-sectional view showing a cleaning tank of the electroless plating unit;

FIG. 17 is a schematic diagram of the electroless plating unit;

FIG. 18 is a vertical cross-sectional view showing a post-treatment and drying unit;

FIG. 19 is a plan view showing the post-treatment and drying unit;

FIG. 20 is a vertical sectional view of an example of a heat treatment unit;

FIG. 21 is a transverse sectional view of FIG. 20;

FIG. 22 is a graph showing the results of X-ray diffraction analysis of cobalt phosphinate used in the Examples;

FIG. 23 is a diagram (photograph) showing a protective film (plated film) of CoP alloy deposited on the surfaces of copper interconnects in Example 1;

FIG. 24 is a diagram (photograph) showing a protective film (plated film) of CoWP alloy deposited on the surfaces of copper interconnects in Example 2; and

FIG. 25 is a photograph of a cross-section of the copper-interconnects region of a sample substrate after electroless plating carried out in Example 3.

### DETAILED DESCRIPTION OF THE PREFERRED EMBODIMENTS

Preferred embodiment of the present invention will now be described with reference to the drawings. The embodiments illustrate the case of embedding copper as an interconnect material into fine interconnect recesses provided in the surface of a substrate, such as a semiconductor wafer, to form interconnects of copper, and forming a protective film selectively on surfaces of the interconnects (copper interconnects) to protect the interconnects.

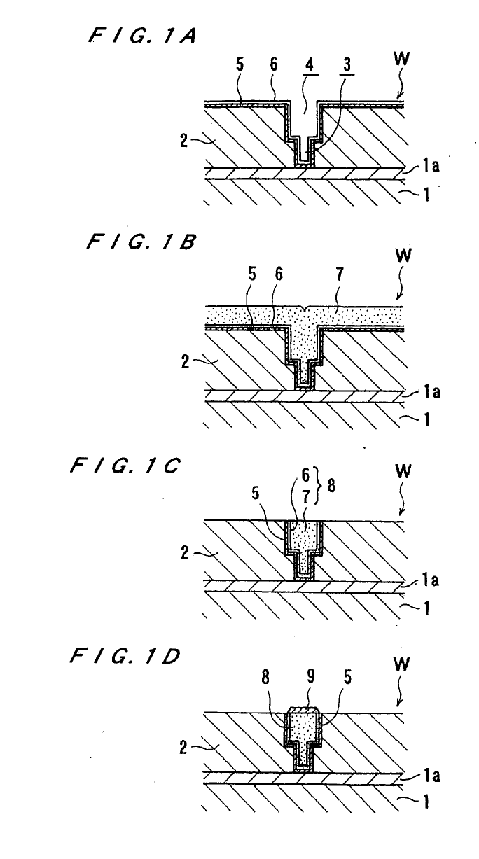

FIGS. 1A through 1D illustrate an example of forming copper interconnects protected with a protective film. As shown in FIG. 1A, an insulating film 2, such as an oxide film of SiO₂ or a film of low-k material, is deposited on a conductive layer 1a formed on a semiconductor base 1 having formed semiconductor devices. Via holes 3 and interconnect trenches 4 are formed in the insulating film 2 by performing a lithography/etching technique so as to provide fine recesses for interconnects. Thereafter, a barrier layer 5 of Ti, TaN, Ta, TaN, WN, or TiSiN, or the like is formed on the insulating film 2, and a seed layer 6 as a feeding layer for electroplating is formed on the barrier layer 5 by sputtering or the like.

Then, as shown in FIG. 1B, copper plating is performed on a surface of a substrate W to fill the via holes 3 and the interconnect trenches 4 with copper and, at the same time, deposit a copper layer 7 on the insulating film 2. Thereafter, the barrier layer 5, the seed layer 6 and the copper layer 7 on the insulating film 2 are removed by chemical mechanical polishing (CMP) or the like so as to leave copper filled in the via holes 3 and the trenches 4, and have a surface of the insulating film 2 lie substantially on the same plane as this copper. Interconnects (copper interconnects) 8 composed of the seed layer 6 and the copper layer 7 are thus formed in the insulating film 2, as shown in FIG. 1C.

Then, as shown in FIG. 1D, electroless plating is performed on a surface of the substrate W to selectively form a protective film 9 on surfaces of the interconnects 8, thereby covering and protecting the surfaces of the interconnects 8 with the protective film 9.

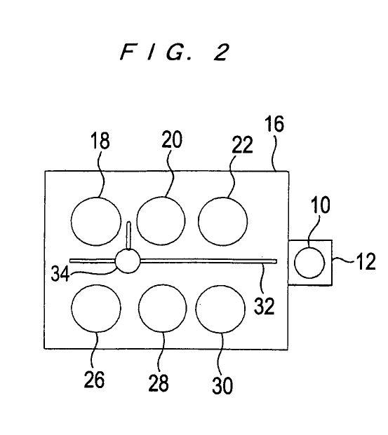

FIG. 2 shows a horizontal arrangement of a substrate processing apparatus for use the formation of a protective film according to an embodiment of the present invention. As shown in FIG. 2, this substrate processing apparatus has a loading/unloading unit 12 for placing and receiving a substrate cassette 10 housing substrates W (see FIG. 1C) having interconnects 8 made of copper or the like formed in interconnect fine recesses 4 formed in a surface thereof. A first pre-treatment unit 18 for performing a pre-plating process of a substrate W, i.e., for cleaning a surface of a substrate W, a second pre-treatment unit 20 for imparting a catalyst to exposed surfaces of cleaned interconnects 8 to activate the exposed surfaces, and an electroless plating unit 22 for performing an electroless plating process on the surface (surface to be processed) of the substrate W are disposed in series along one of long sides of a rectangular housing 16 having an exhaust system.

A post-treatment unit 26 for performing a post-treatment of the substrate W to improve the selectivity of a protective film 9 (see FIG. 1D) formed on the surfaces of the interconnects 8 by the electroless plating process, a drying unit 28 for drying the substrate W after the post-treatment, and a heat treatment unit 30 for performing a heat treatment (annealing) to the dried substrate W 8 are disposed in series along the other of the long sides of the housing 16. Further, a transfer robot 34 movable along a rail 32 in parallel to the long sides of the housing 16 and for transferring a substrate between these units and the substrate cassette 10 placed on the loading/unloading unit 12 is disposed so as to be interposed between these units linearly arranged.

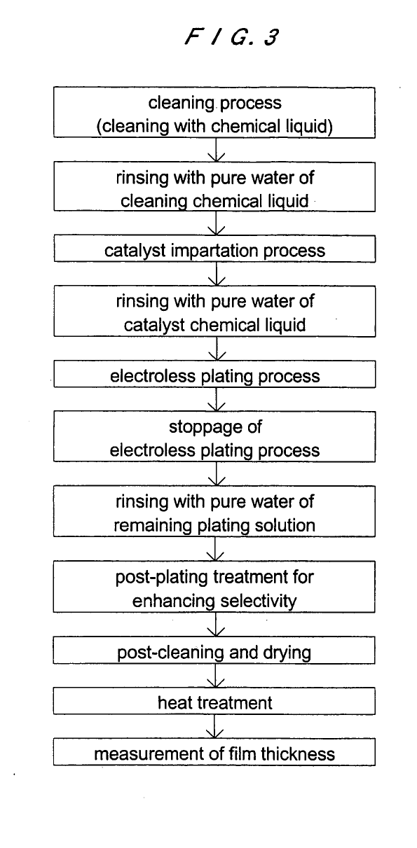

Next, a series of electroless plating processing by this substrate processing apparatus will be described with reference to FIG. 3. In this example, as shown in FIGS. 1C and 1D, a protective film (cap material) 9 of CoP or a CoWP alloy is selectively formed to protect the interconnects 8.

First, a dried substrate W having interconnects 8 formed in a surface thereof is taken by the transfer robot 34 out of the substrate cassette 10, which houses substrates W in a state such that front surfaces of the substrates W face upward (in a face-up manner), placed on the loading/unloading unit 12, and is transferred to the first pre-treatment unit 18. In the first pre-treatment unit 18, the substrate W is held face down, and a cleaning process (cleaning with chemical liquid) is performed as a pre-plating process on a surface of the substrate W. Specifically, a chemical liquid such as a dilute H₂SO₄ solution, for example at a temperature of 25° C., is sprayed toward the surface of the substrate W to remove CMP residues such as copper remaining on a surface of an insulating film 2 (see FIG. 1C) or oxides on an interconnect film. Thereafter, the surface of the substrate W is rinsed (cleaned) with a rinsing liquid such as pure water to remove a cleaning chemical liquid remaining on the surface of the substrate W.

Next, the substrate W after the cleaning process and the rinsing process is transferred to the second pre-treatment unit 20 by the transfer robot 34. In the second pre-treatment unit 20, the substrate W is held face down, and a catalyst impartation process is performed on the surface of the substrate W. Specifically, a mixed solution of PdCl₂/HCl or the like, for example at a temperature of 25° C., is ejected toward the surface of the substrate W to adhere Pd as a catalyst to the surfaces of the interconnects 8. More specifically, Pd cores are formed as catalyst cores (seeds) on the surfaces of the interconnects 8 to activate exposed surfaces of the interconnects 8. Then, a catalyst chemical liquid remaining on the surface of the substrate W is rinsed (cleaned) with a rinsing liquid such as pure water.

Thus, when a catalyst is imparted to the surface of the substrate W, it is possible to enhance the selectivity of electroless plating. Various materials can be used as a catalyst metal. However, it is desirable to use Pd in view of a reaction rate, easiness of the control, or the like.

The substrate W after the catalyst impartation and rinsing is transferred by the transfer robot 34 to the electroless plating unit 22, where the substrate W is held face down and its front surface is brought into contact with an electroless plating bath to carry out electroless plating process of the surface of the substrate, thereby forming a protective film (cap material) 9 of a CoP or CoWP alloy selectively on the surfaces of interconnects 8, as shown in FIG. 1D. The film thickness of the protective film 9 is generally 0.1 to 500 nm, preferably 1 to 200 nm, more preferably 10 to 100 nm.

The electroless plating bath used in the electroless plating unit 22 comprises as essential components cobalt ions, phosphinate ions and a complexing agent, uses cobalt phosphinate (cobalt hypophosphite) as a main supply source of the cobalt ions and the phosphinate ions, and does not substantially contain alkali metal ions.

Cobalt ions and phosphinate ions in the electroless plating bath are mainly derived from cobalt phosphinate (Co(H₂PO₂)₂). Cobalt phosphinate maybe prepared, for example, by adding cobalt hydroxide to hypophosphorous acid (phosphinic acid) or by the double decomposition reaction between barium hypophosphite and cobalt sulfate.

While cobalt phosphinate is employed as a main supply source of cobalt ions and phosphinate ions in the electroless plating bath, it is possible to use an additional compound containing a cobalt or phosphinic acid moiety for increasing one of these components, as necessary. For example, when it is intended to increase only the cobalt ion concentration of the plating bath, a cobalt salt, such as cobalt sulfate, cobalt nitrate or cobalt chloride, may be used. When it is intended to increase only the phosphinate ion concentration, phosphinic acid, ammonium phosphinate, or the like may be added in an appropriate amount to the plating bath. Such an additional compound should not contain an alkali metal.

Examples of the complexing agent for use in the electroless plating solution include carboxylic acids, such as acetic acid, oxalic acid and malonic acid, and their salts; hydroxycarboxylic acids, such as tartaric acid, citric acid and malic acid, and their salts; aminocarboxylic acids, such as glycine and alanine, and their salts; amines, such as ethylenediamine, and their salts; and ammonia. These compounds may be used either singly or in combination of two or more.

Phosphinate ions and cobalt ions are used each generally in an amount of 0.001 to 1 mol/L, preferably 0.01 to 0.3 mol/L in the electroless plating bath. The complexing agent is used generally in an amount of 0.001 to 1.5 mol/L, preferably 0.01 to 1 mol/L.

The above-described electroless plating bath is used to form a protective film 9 of a CoP alloy. In addition to the above essential components, the electroless plating bath may also contain a high-melting metal compound, and such a plating bath can deposit a plated film composed of an alloy comprising cobalt and the high-melting metal.

The high-melting metal contained in the high-melting metal compound may be exemplified by tungsten and molybdenum. The inclusion of tungsten enables the formation of a protective film 9 of a CoWP alloy. Examples of tungsten-containing compounds include tungsten trioxide, tungstic acid, ammonium tungstate, and ammonium paratungstate. On the other hand, examples of molybdenum-containing compounds include molybdenum trioxide, molybdic acid, ammonium molybdate, and ammonium paramolybdate.

Heteropolyacids such as phosphotungstic acid, ammonium phosphotungstate, silicotungstic acid, ammoniumsilicotungstate, phosphomolybdic acid and ammonium phosphomolybdate, and their salts may also be used as the high-melting metal compound.

The concentration of the high-melting metal compound in the electroless plating bath is preferably 0.0001 to 1 mol/L in terms of the concentration of the high-melting metal element, and more preferably 0.001 to 0.1 mol/L.

Besides the above-described basic components, as necessary, a pH adjustment agent or a pH buffering agent may be added to the electroless plating bath.

Examples of usable pH adjustment agents include ammonia water and organic alkalis, such as tetramethylammonium hydroxide, tetraethylammonium hydroxide and choline. Examples of usable pH buffering agents include boric acid, ammonium sulfate and ammonium tetraborate.

Further, in addition to the above-described components, the electroless plating bath may also contain known additives, such as a bath stabilizer and a wetting agent and the like. Examples of the bath stabilizer include a compound containing a heavy metal, such as lead (Pb) or bismuth (Bi), and a compound containing sulfur, such as thiodiglycolic acid. Various surfactants, including nonionic, anionic and cationic surfactants, may be used as the wetting agent.

Also for the above-described optional components, such as the pH adjustment agent, compounds not containing an alkali metal, such as sodium, should be selected.

There is no particular limitation on the method of preparing the electroless plating bath and the method of carrying out electroless plating, and those methods as commonly used for electroless cobalt plating or electroless cobalt alloy plating may be employed. For example, the plating bath may be prepared by the common method of mixing the above-described components. The electroless plating bath is adjusted generally at a pH of 7 to 14, preferably 8 to 12. In carrying out electroless plating, the electroless plating bath is adjusted generally at a temperature of 20 to 100° C., preferably 50 to 90° C.

The following is a preferable example of the composition of the present electroless plating bath for CoWP alloy plating.

Electroless plating bath composition

| | | |
|---|---|---|
| Cobalt phosphinate | 0.01-0.3 | mol/L |
| Ammonium paratungstate ((NH₄)W₁₂O₄₁) | 0.001-0.01 | ml/L |
| Citric acid (complexing agent) | 0.01-1 | mol/L |
| Phosphinic acid | 0-0.05 | mol/L |

The deposition rate of the protective film 9 is preferably made 0.1 to 38 nm/min. Since the deposition rate is directly linked to the productivity, it cannot be made very low. Too high a deposition rate, on the other hand, cannot ensure the uniformity and the reproducibility of plating. The film thickness of the protective film 9 is generally 0.1 to 500 nm, and it is desirable to employ a deposition rate of 0.1 to 38 nm/min to obtain such a film thickness. The deposition rate can be controlled both by the compositional conditions, such as pH, of the plating solution, and by the reaction conditions, such as the reaction temperature.

After lifting the substrate W from the electroless plating bath, a stop liquid of a neutral liquid having a pH of 6 to 7.5 is brought into contact with the surface of the substrate W to thereby stop the electroless plating process. By thus promptly stopping the plating reaction immediately after lifting the substrate W from the electroless plating bath, the plated film (protective film) can be prevented from becoming uneven.

Thereafter, the plating solution remaining on the surface of the substrate is rinsed off (cleaned) with a rinsing liquid such as pure water. The protective film 9 of a CoP or CoWP alloy is thus formed selectively on the surfaces of interconnects 8 to protect the interconnects 8.

Next, the substrate W after the electroless plating is transferred by the transfer robot 34 to the post-treatment unit 26, where the substrate W is subjected to post-plating treatment in order to enhance the selectivity of the protective film (plated film) 9 formed on the surface of the substrate W and thereby increase the yield. In particular, while applying a physical force to the surface of the substrate W, for example, by roll scrub cleaning or pencil cleaning, a post-plating treatment liquid (chemical liquid) is supplied onto the surface of the substrate W to thereby completely remove plating residues, such as fine metal particles, from the insulating film 2, thus enhancing the selectivity of plating.

The substrate W after the post-treatment is transferred by the transfer robot 34 to the drying unit 28, where the substrate W is rinsed, according to necessity, and then rotated at a high speed to spin-dry the substrate W.

The substrate W after spin-drying is transferred by the transfer robot 34 to the heat treatment unit 30, where the substrate W after the post-treatment is subjected to heat treatment (annealing) to modify the protective film 9. The temperature necessary for modification of the protective film 9 is at least 120° C., also taking into account the practical processing time. Further, taking into account the heat resistance of materials constituting devices, the heat treatment temperature preferably should not exceed 450° C. Thus, the heat treatment (annealing) temperature is, for example, 120 to 450° C. The heat treatment of the substrate W can improve the barrier properties of the protective film (plated film) formed on the exposed surfaces of interconnects and can increase the adhesion of the protective film to the interconnects.

Next, the substrate W after the heat treatment is returned by the transfer robot 34 to the substrate cassette 10 mounted in the loading/unloading unit 12.

Next, there will be described below the details of various units provided in the substrate processing apparatus shown in FIG. 2.

The first pre-treatment unit 18 and the second pre-treatment unit 20 use different treatment liquids (chemical liquids) but have the same structure which employs a two-liquid separation system to prevent the different liquids from being mixed with each other. While a peripheral portion of a lower surface of the substrate W, which is a surface to be processed (front face), transferred in a face-down manner is sealed, the substrate W is fixed by pressing a rear face of the substrate.

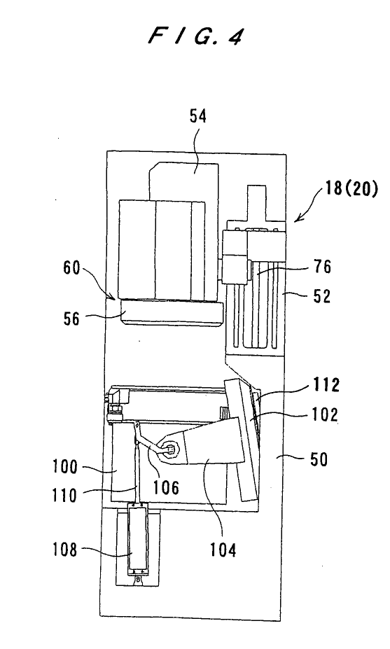

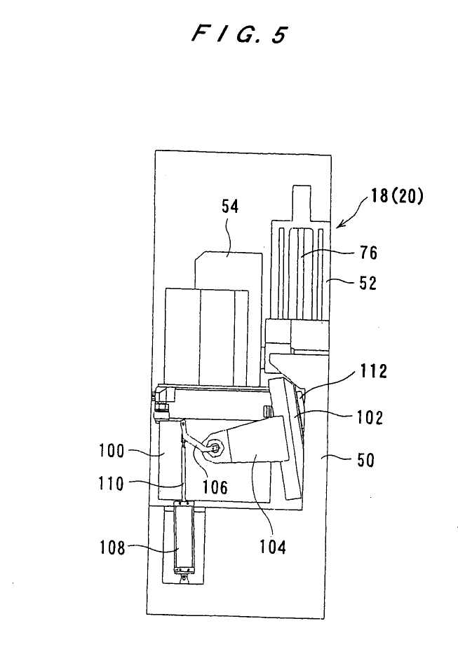

As shown in FIGS. 4 through 7, each of the treatment units 18 and 20 includes a fixed frame 52 mounted on an upper portion of a frame 50, and a movable frame 54 which is vertically movable relative to the fixed frame 52. A processing head 60, which has a bottomed cylindrical housing portion 56 opened downward and a substrate holder 58, is suspended from and supported by the movable frame 54. Specifically, a servomotor 62 for rotating the head is mounted on the movable frame 54, and the housing portion 56 of the processing head 60 is coupled to a lower end of an output shaft (hollow shaft) 64, which extends downward, of the servomotor 62.

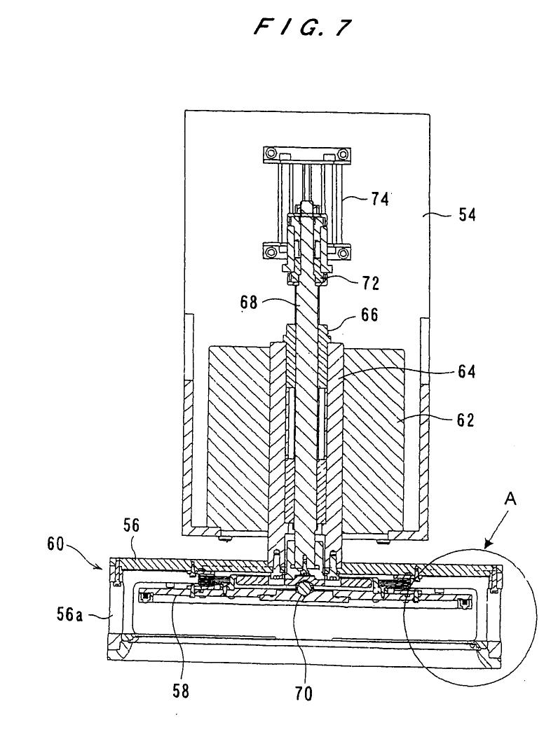

As shown in FIG. 7, a vertical shaft 68, which rotates together with the output shaft 64 via a spline 66, is inserted in the output shaft 64, and the substrate holder 58 of the processing head 60 is coupled to a lower end of the vertical shaft 68 via a ball joint 70. The substrate holder 58 is positioned within the housing portion 56. An upper end of the vertical shaft 68 is coupled via a bearing 72 and a bracket to a cylinder 74 for vertically moving a fixed ring, which is secured to the movable frame 54. Thus, by actuation of the cylinder 74 for vertically movement, the vertical shaft 68 is vertically moved independently of the output shaft 64.

Linear guides 76, which extend vertically and serve to guide vertical movement of the movable frame 54, are mounted to the fixed frame 52, so that the movable frame 54 is moved vertically with a guide of the linear guides 76 by actuation of a cylinder (not shown) for vertically moving the head.

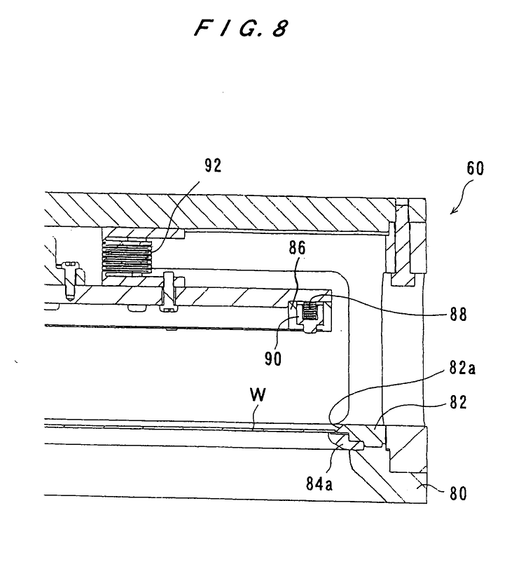

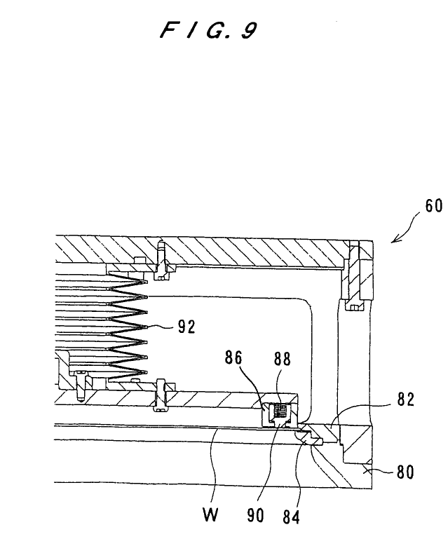

Substrate insertion windows 56a for inserting the substrate W into the housing portion 56 are formed in a circumferential wall of the housing portion 56 of the processing head 60. Further, as shown in FIGS. 8 and 9, a seal ring 84a is disposed in a lower portion of the housing portion 56 of the processing head 60 with an outer peripheral portion of the seal ring 84a being sandwiched between a main frame 80 made of, for example, PEEK and a guide frame 82 made of, for example, polyethylene. The seal ring 84a is brought into abutment against a peripheral portion of a lower surface of the substrate W to seal the peripheral portion.

Meanwhile, a substrate fixing ring 86 is fixed to a peripheral portion of a lower surface of the substrate holder 58. Columnar pushers 90 protrude downward from a lower surface of the substrate fixing ring 86 by elastic forces of springs 88 disposed within the substrate fixing ring 86 of the substrate holder 58. Further, a flexible cylindrical bellows plate 92 made of, for example, Teflon (registered trademark) is disposed between an upper surface of the substrate holder 58 and an upper wall of the housing portion 56 to hermetically seal therein.

When the substrate holder 58 is in a lifted position, a substrate W is inserted through the substrate insertion window 56a into the housing portion 56. The substrate W is then guided by a tapered surface 82a provided in an inner circumferential surface of the guide frame 82, and positioned and placed at a predetermined position on an upper surface of the seal ring 84a. In this state, the substrate holder 58 is lowered so as to bring the pushers 90 of the substrate fixing ring 86 into contact with an upper surface of the substrate W. The substrate holder 58 is further lowered so as to press the substrate W downward by the elastic forces of the springs 88. Thus, the seal ring 84a is brought into contact with a peripheral portion of the front face (lower surface) of the substrate W under pressure to seal the peripheral portion while clamping and holding the substrate W between the housing portion 56 and the substrate holder 58.

When the servomotor 62 for rotating the head is driven in a state such that the substrate W is thus held by the substrate holder 58, the output shaft 64 and the vertical shaft 68 inserted in the output shaft 64 rotate together with via the spline 66, so that the substrate holder 58 rotates together with the housing portion 56.

At a position below the processing head 60, there is provided a treatment tank 100 having an outer tank 100a and an inner tank 100b, which has a slightly larger inside diameter than the outside diameter of the processing head 60 and is opened upward. A pair of leg portions 104, which is mounted to a lid 102, is rotatably supported on an outer circumferential portion of the treatment tank 100. Further, a crank 106 is integrally coupled to each leg portion 106, and a free end of the crank 106 is rotatably coupled to a rod 110 of a cylinder 108 for moving the lid. Thus, by actuation of the cylinder 108 for moving the lid, the lid 102 is moved between a treatment position at which the lid 102 covers a top opening portion of the treatment tank 100 and a retracting position beside the treatment tank 100. On the front face (upper surface) of the lid 102, there is provided a nozzle plate 112 having a large number of ejection nozzles 112 for outwardly (upwardly) ejecting a cleaning liquid (rinsing liquid) such as ultrapure water.

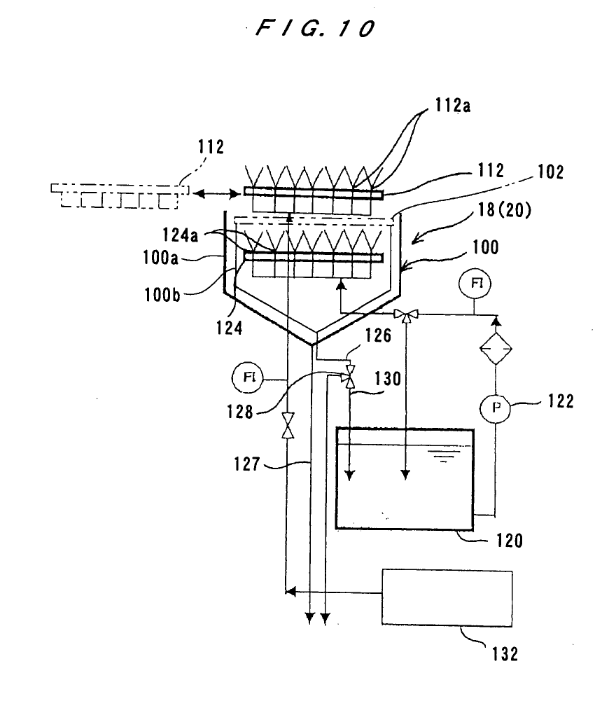

Further, as shown in FIG. 10, a nozzle plate 124 having a plurality of ejection nozzles 124a for upwardly ejecting a chemical liquid supplied from a chemical liquid tank 120 by actuation of a chemical liquid pump 122 is provided in the inner tank 100b of the treatment tank 100 in such a manner that the ejection nozzles 124a are equally distributed over the entire surface of a horizontal cross-section of the inner tank 100b. A drainpipe 126 for draining a chemical liquid (waste liquid) to the outside is connected to the bottom of the inner tank 100b. A three-way valve 128 is provided in the drainpipe 126, and the chemical liquid (waste liquid) is returned to the chemical liquid tank 120 through a return pipe 130 connected to one of outlet ports of the three-way valve 128 so as to reuse the chemical liquid, as needed. Further, in this embodiment, the nozzle plate 112 provided on the front face (upper surface) of the lid 102 is connected to a cleaning liquid supply source 132 for supplying a cleaning liquid (rinsing liquid) such as pure water. Furthermore, a drainpipe 127 is connected to a bottom surface of the outer tank 100a.

By lowering the processing head 60 holding the substrate so as to cover the top opening portion of the treatment tank 100 with the processing head 60 and then ejecting a chemical liquid from the ejection nozzles 124a of the nozzle plate 124 disposed in the inner tank 100b of the treatment tank 100 toward the substrate W, the chemical liquid can be ejected uniformly onto the entire lower surface (surface to be processed) of the substrate W and discharged through the drainpipe 126 to the outside while preventing the chemical liquid from being scattered to the outside. Further, by lifting up the processing head 60, closing the top opening portion of the treatment tank 100 with the lid 102, and then ejecting a cleaning liquid (rinsing liquid) such as pure water from the ejection nozzles 112a of the nozzle plate 112 disposed on the upper surface of the lid 102 toward the substrate W held in the processing head 60, a rinsing process (cleaning process) for a chemical liquid remaining on the surface of the substrate is performed. Since the cleaning liquid passes through a clearance between the outer tank 100a and the inner tank 100b and is discharged through the drainpipe 127, the cleaning liquid is prevented from flowing into the inner tank 100b and from being mixed with the chemical liquid.

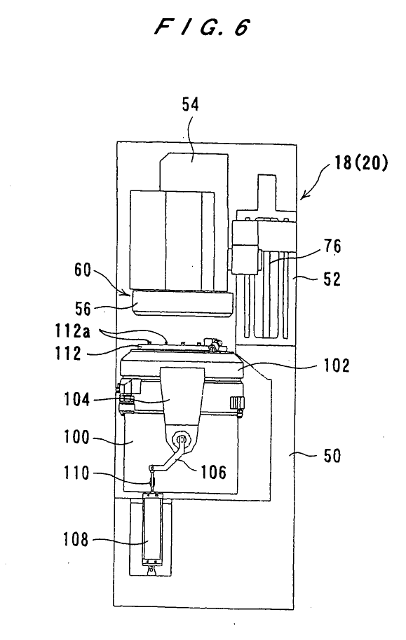

According to the pre-treatment units 18 and 20, the substrate W is inserted into and held in the processing head 60 when the processing head 60 is in the lifted position, as shown in FIG. 4. Thereafter, as shown in FIG. 5, the processing head 60 is lowered to a position at which the processing head 60 covers the top opening portion of the treatment tank 100. While rotating the processing head 60 and thereby rotating the substrate W held in the processing head 60, a chemical liquid is ejected from the ejection nozzles 124a of the nozzle plate 124 disposed in the treatment tank 100 toward the substrate W to thereby eject the chemical liquid uniformly onto the entire surface of the substrate W. The processing head 60 is lifted up and stopped at a predetermined position. As shown in FIG. 6, the lid 102 in the retracting position is moved to a position at which the lid 102 covers the top opening portion of the treatment tank 100. Then, a cleaning liquid (rinsing liquid) such as pure water is ejected from the ejection nozzles 112a of the nozzle plate 112 disposed on the upper surface of the lid 102 toward the rotating substrate W held in the processing head 60. Thus, a process of the substrate W with a chemical liquid and a cleaning (rinsing) process of the substrate W with a rinsing liquid can be performed without mixing these two liquids.

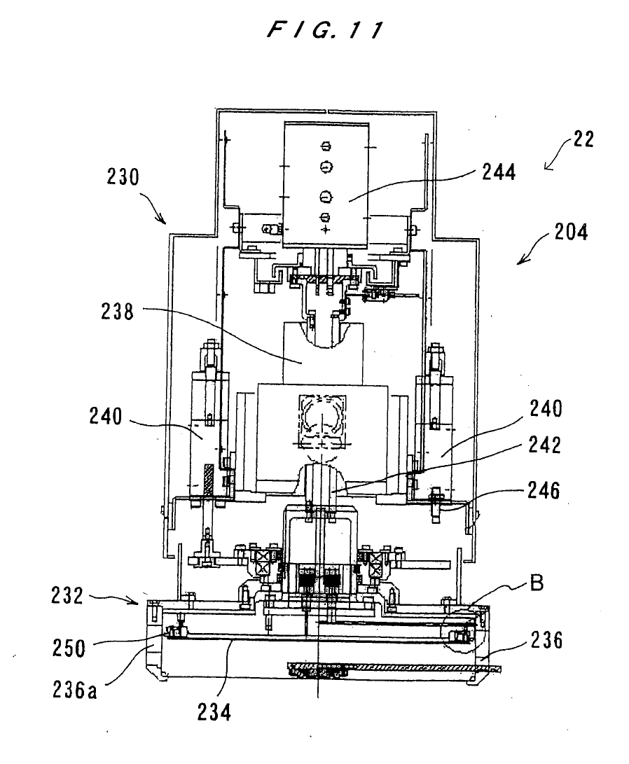

FIGS. 11 through 17 show the electroless plating unit 22. This electroless plating unit 22 has a plating tank 200 (see FIG. 17) and a substrate head 204 disposed above the plating tank 200 for detachably holding a substrate W.

As shown in detail in FIG. 11, the substrate head 204 has a housing portion 230 and a head portion 232. The head portion 232 is mainly composed of a suction head 234 and a substrate receiver 236 surrounding the suction head 234. A motor 238 for rotating the substrate and cylinders 240 for driving the substrate receiver are housed in the housing portion 230. An upper end of an output shaft (hollow shaft) 242 of the motor 238 for rotating the substrate is coupled to a rotary joint 244, and a lower end of the output shaft is coupled to the suction head 234 of the head portion 232, respectively. Rods of the cylinders 240 for driving the substrate receiver are coupled to the substrate receiver 236 of the head portion 232. Stoppers 246 are provided in the housing portion 230 for mechanically limiting upward movement of the substrate receiver 236.

A splined structure is provided between the suction head 234 and the substrate receiver 236. The substrate receiver 236 is vertically moved relative to the suction head 234 by actuation of the cylinders 240 for driving the substrate receiver. When the motor 238 for rotating the substrate is driven to rotate the output shaft 242, the suction head 234 and the substrate receiver 236 are rotated in unison with each other according to the rotation of the output shaft 242.

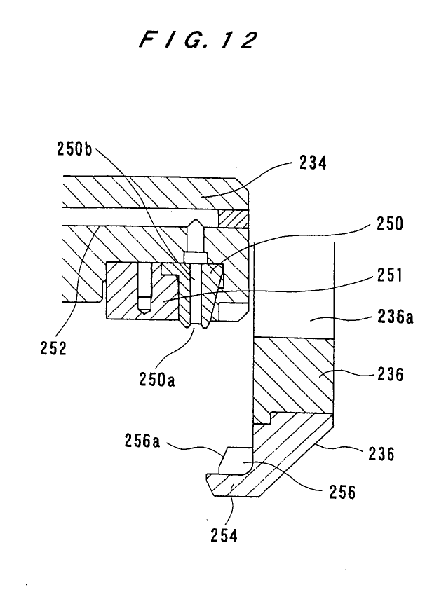

As shown in detail in FIGS. 12 through 14, a suction ring 250 for attracting and holding a substrate W against its lower surface to be sealed is mounted on a lower circumferential edge of the suction head 234 by a presser ring 251. A recess 250a continuously defined in a lower surface of the suction ring 250 in a circumferential direction communicates with a vacuum line 252 extending through the suction head 234 through a communication hole 250b defined in the suction ring 250. By evacuating the recess 250a, the substrate W is attracted and held. The substrate W is released by supplying N₂ into the vacuum line 252.

Meanwhile, the substrate receiver 236 is in the form of a bottomed cylinder opened downward. Substrate insertion windows 236a for inserting the substrate W into the substrate receiver 236 are defined in a circumferential wall of the substrate receiver 236. A disk-like ledge 254 projecting inward is provided at a lower end of the substrate receiver 236. A protrusion 256 having an inner tapered surface 256a for guiding the substrate W is provided on an upper portion of the ledge 254.

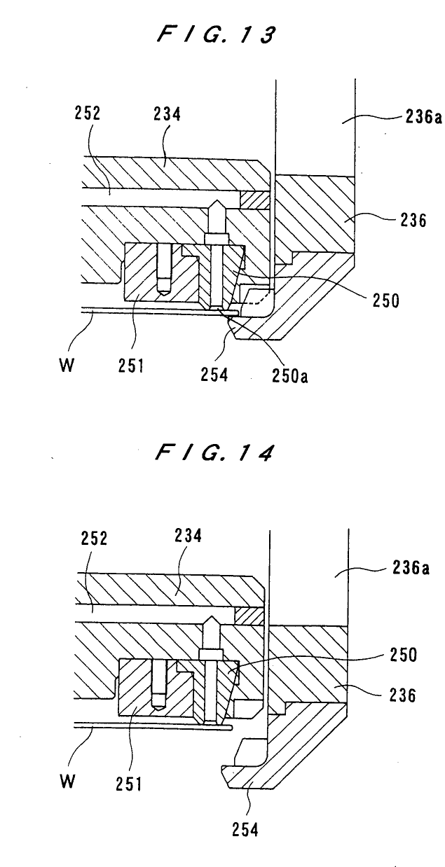

As shown in FIG. 12, when the substrate receiver 236 is in a lowered position, the substrate W is inserted through the substrate insertion window 236a into the substrate receiver 236. The substrate W is then guided by the tapered surface 256a of the protrusion 256 and positioned and placed at a predetermined position on an upper surface of the ledge 254 of the substrate receiver 236. In this state, as shown in FIG. 13, the substrate receiver 236 is lifted up so as to bring the upper surface of the substrate W placed on the ledge 254 of the substrate receiver 236 into abutment against the suction ring 250 of the suction head 234. Then, the recess 250a in the vacuum ring 250 is evacuated through the vacuum line 252 to attract and hold the substrate W while sealing the upper peripheral edge surface of the substrate W against the lower surface of the suction ring 250. For performing a plating process, as shown in FIG. 14, the substrate receiver 236 is lowered several millimeters to separate the substrate W from the ledge 254 so that the substrate W is attracted and held only by the suction ring 250. Thus, it is possible to prevent the front face (lower surface) of the peripheral edge portion of the substrate W from not being plated because of the presence of the ledge 254.

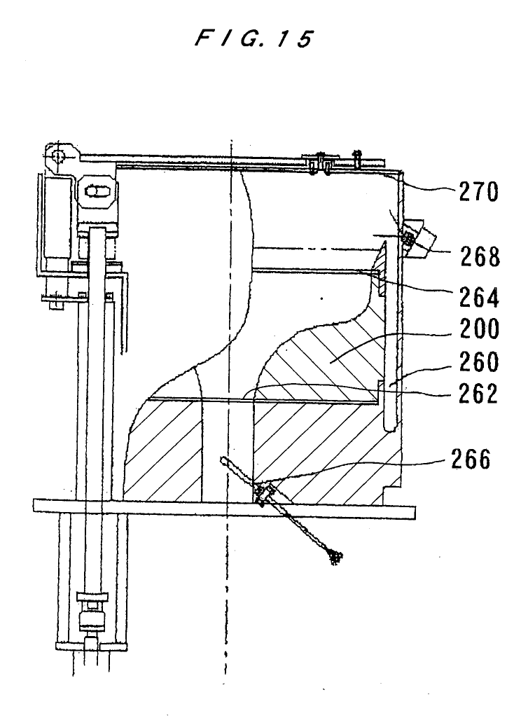

FIG. 15 shows the details of the plating tank 200. The plating tank 200 is connected at the bottom to a plating solution supply pipe 308 (see FIG. 17) and is provided in the peripheral wall with a plating solution recovery gutter 260. In the plating tank 200, there are disposed two current plates 262 and 264 for stabilizing the flow of a plating solution flowing upward in the plating tank 200. A thermometer 266 for measuring the temperature of the plating solution to be introduced into the plating tank 200 is disposed at the bottom of the plating tank 200. Further, on the outer surface of the peripheral wall of the plating tank 200 and at a position slightly higher than the liquid level of the plating solution held in the plating tank 200, there is provided an ejection nozzle 268 for ejecting a stop solution which is a neutral liquid having a pH of 6 to 7.5, for example, pure water, slightly upward with respect to a diametrical direction in the plating tank 200. After the plating, the substrate W held in the head portion 232 is lifted up and stopped at a position slightly above the liquid level of the plating solution. In this state, pure water (stop solution) is ejected from the ejection nozzle 268 toward the substrate W to cool the substrate W immediately, thereby preventing progress of plating by the plating solution remaining on the substrate W.

Further, at a top opening portion of the plating tank 200, there is provided an openable and closable plating tank cover 270 which closes the top opening portion of the plating tank 200 so as to prevent unnecessary evaporation of the plating solution from the plating tank 200 when the plating process is not performed, such as at the time of idling.

As shown in FIG. 17, the plating tank 200 is connected at the bottom to a plating solution supply pipe 308 extending from a plating solution reservoir tank 302 and having a plating solution supply pump 304 and a three-way valve 306. Thus, during a plating process, a plating solution is supplied from the bottom of the plating tank 200 into the plating tank 200, and an overflowing plating solution is recovered to the plating solution reservoir tank 302 by the plating solution recovery gutter 260. Thus, the plating solution can be circulated. A plating solution return pipe 312 for returning the plating solution to the plating solution reservoir tank 302 is connected to one of ports of the three-way valve 306. Accordingly, the plating solution can be circulated even at the time of a standby for plating.

The thermometer 266 provided in the vicinity of the bottom of the plating tank 200 measures the temperature of the plating solution to be introduced into the plating tank 200 and controls a heater 320 based on the measurement results.

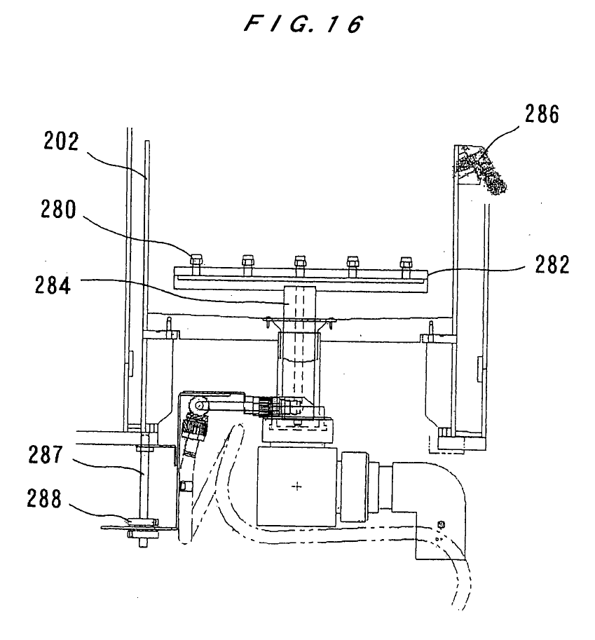

FIG. 16 shows the details of a cleaning tank 202 provided beside the plating tank 200. At the bottom of the cleaning tank 202, there is provided a nozzle plate 282 to which a plurality of ejection nozzles 280 for ejecting a rinsing liquid such as pure water upward are attached. The nozzle plate 282 is coupled to an upper end of a nozzle vertical shaft 284. The nozzle vertical shaft 284 can be moved vertically by changing positions of engagement between a nozzle position adjustment screw 287 and a nut 288 engaging the screw 287 so as to optimize a distance between the ejection nozzles 280 and the substrate W disposed above the ejection nozzles 280.

Further, on the outer surface of the peripheral wall of the cleaning tank 202 and at a position higher than the ejection nozzles 280, there is provided a head cleaning nozzle 286 for ejecting a cleaning liquid such as pure water slightly downward with respect to a diametric direction in the cleaning tank 202 to blow the cleaning liquid to at least a portion of the head portion 232 of the substrate head 204 which is brought into contact with the plating solution.

In the cleaning tank 202, the substrate W held in the head portion 232 of the substrate head 204 is located at a predetermined position in the cleaning tank 202. A cleaning liquid (rinsing liquid) such as pure water is ejected from the ejection nozzles 280 to clean (rinse) the substrate W. At that time, a cleaning liquid such as pure water is ejected from the head cleaning nozzle 286 to clean, with the cleaning liquid, at least a portion of the head portion 232 of the substrate head 204 which is brought into contact with the plating solution, thereby preventing a deposit from accumulating on a portion which is immersed in the plating solution.

According to this electroless plating unit 22, when the substrate head 204 is in a lifted position, the substrate W is attracted to and held in the head portion 232 of the substrate head 204, as described above, while the plating solution in the plating tank 200 is circulated.

When a plating process is performed, the plating tank cover 270 of the plating tank 200 is opened, and the substrate head 204 is lowered while being rotated. Thus, the substrate W held in the head portion 232 is immersed in the plating solution in the plating tank 200.

After immersing the substrate W in the plating solution for a predetermined period of time, the substrate head 204 is raised to lift the substrate W from the plating solution in the plating tank 200 and, as needed, pure water (stop solution) is ejected from the ejection nozzles 268 toward the substrate W to immediately cool the substrate W, as described above. The substrate head 204 is further raised to lift the substrate W to a position above the plating tank 200, and the rotation of the substrate head 204 is stopped.

Next, while the substrate W is being attracted to and held in the head portion 232 of the substrate head 204, the substrate head 204 is moved to a position right above the cleaning tank 202. While the substrate head 204 is rotated, the substrate head 204 is lowered to a predetermined position in the cleaning tank 202. A cleaning liquid (rinsing liquid) such as pure water is ejected from the ejection nozzles 280 to clean (rinse) the substrate W. At that time, a cleaning liquid such as pure water is ejected from the head cleaning nozzle 286 to clean at least a portion the head portion 232 of the substrate head 204 which is brought into contact with the plating solution.

After completion of cleaning of the substrate W, the rotation of the substrate head 204 is stopped, and the substrate head 204 is raised to lift the substrate W to a position above the cleaning tank 202. Further, the substrate head 204 is moved to a transfer position between the transfer robot 34 and the substrate head 204. Then, the substrate W is delivered to the transfer robot 34 and is transferred to a subsequent process by the transfer robot 16.

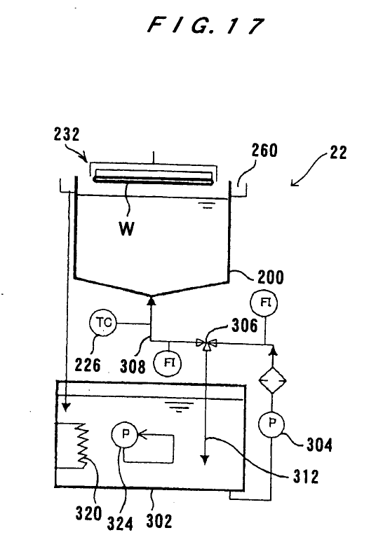

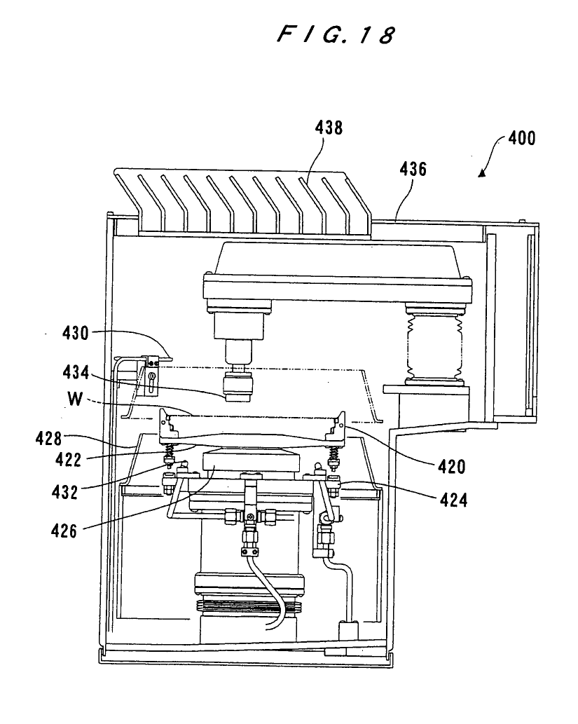

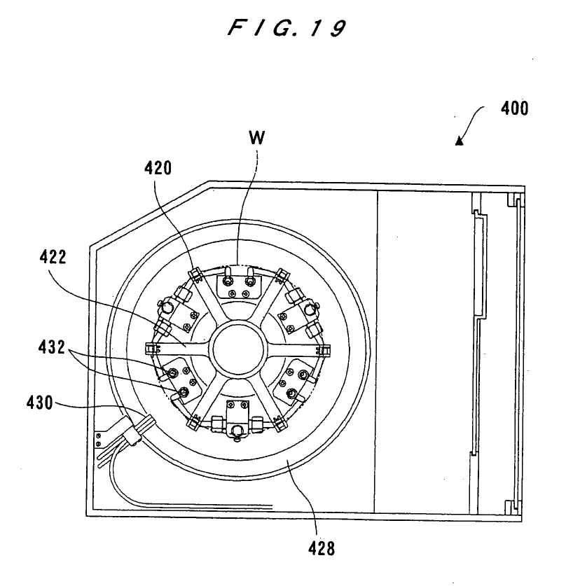

FIGS. 18 and 19 show a post-treatment and drying unit 400 into which the post-treatment unit 24 and the drying unit 26 shown in FIG. 2 are combined to continuously perform a post-treatment and a drying process of a substrate. Specifically, the post-treatment and drying unit 400 first performs chemical cleaning (post-treatment) and pure water cleaning (rinsing), and then completely dries the substrate W after the cleaning by spindle rotation. The post-treatment and drying unit 400 has a substrate stage 422 having a clamp mechanism 420 for clamping an edge portion of the substrate W, and a vertically movable plate 424, for mounting and removing a substrate, which opens and closes the clamp mechanism 420.

The substrate stage 422 is coupled to an upper end of a spindle 426 which is rotated at a high speed by actuation of a motor (not shown) for rotating the spindle. Further, a cleaning cup 428 for preventing a treatment liquid from being scattered is disposed around the substrate W held by the clamp mechanism 420. The cleaning cup 428 is vertically moved by actuation of a cylinder, which is not shown.

Further, the post-treatment and drying unit 400 has a chemical liquid nozzle 430 for supplying a treatment liquid to the surface of the substrate W held by the clamp mechanism 420, a plurality of pure water nozzles 432 for supplying pure water to a rear face of the substrate W, and a rotatable pencil-type cleaning sponge 434 disposed above the substrate W held by the clamp mechanism 420. The cleaning sponge 434 is attached to a free end of a swingable arm 436 which is swingable in a horizontal direction. Clean air introduction ports 438 for introducing clean air into the unit are provided at an upper portion of the post-treatment and drying unit 400.

With the post-treatment and drying unit 400 having the above structure, the substrate W is held and rotated by the clamp mechanism 420. While the swingable arm 436 is swung, a treatment liquid is supplied from the chemical liquid nozzle 430 to the cleaning sponge 434, and the surface of the substrate W is rubbed with the cleaning sponge 434, thereby performing post-treatment of the surface of the substrate W. Further, pure water is supplied to the rear face of the substrate W from the pure water nozzles 432, and the rear face of the substrate W is simultaneously cleaned (rinsed) by the pure water ejected from the pure water nozzles 432. The cleaned substrate W is spin-dried by rotating the spindle 426 at a high speed.

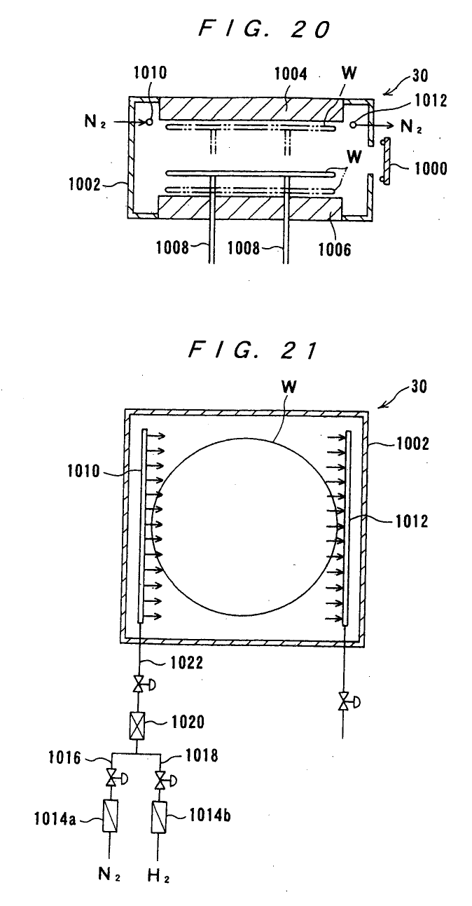

FIGS. 20 and 21 show the heat treatment (annealing) unit 30. The heat treatment unit 30 comprises a chamber 1002 having a gate 1000 for taking in and taking out the substrate W, a hot plate 1004 disposed at an upper position in the chamber 1002 for heating the substrate W to e.g. 400° C., and a cool plate 1006 disposed at a lower position in the chamber 1002 for cooling the substrate W by, for example, flowing a cooling water inside the plate 1006. The heat treatment unit 30 also has a plurality of vertically movable elevating pins 1008 penetrating the cool plate 1006 and extending upward and downward therethrough for placing and holding the substrate W on them. The teat treatment unit 30 further includes a gas introduction pipe 1010 for introducing an antioxidant gas between the substrate W and the hot plate 1004 during heat-treating, and a gas discharge pipe 1012 for discharging the gas which has been introduced from the gas introduction pipe 1010 and flowed between the substrate W and the hot plate 1004. The pipes 1010 and 1012 are disposed on the opposite sides of the hot plate 1004.

The gas introduction pipe 1010 is connected to a mixed gas introduction line 1022 which in turn is connected to a mixer 1020 where a N₂ gas introduced through a N₂ gas introduction line 1016 containing a filter 1014a, and a H₂ gas introduced through a H₂ gas introduction line 1018 containing a filter 1014b are mixed to form a mixed gas, which flows through the line 1022 into the gas introduction pipe 1010.

In operation, the substrate W, which has been carried in the chamber 1002 through the gate 1000, is held on the elevating pins 1008 and the elevating pins 1008 are raised up to a position at which the distance between the substrate W held on the lifting pins 1008 and the hot plate 1004 becomes e.g. about 0.1-1.0 mm. In this state, the substrate W is then heated to e.g. 400° C. through the hot plate 1004 and, at the same time, the antioxidant gas is introduced from the gas introduction pipe 1010 and the gas is allowed to flow between the substrate W and the hot plate 1004 while the gas is discharged from the gas discharge pipe 1012, thereby heat-treating (annealing) the substrate W while preventing its oxidation. The heat treatment may be completed in about several tens of seconds to 60 seconds. The heating temperature of the substrate may be selected in the range of 120-450° C.

After the completion of the heat-treating, the elevating pins 1008 are lowered down to a position at which the distance between the substrate W held on the elevating pins 1008 and the cool plate 1006 becomes e.g. about 0-0.5 mm. In this state, by introducing a cooling water into the cool plate 1006, the substrate W is cooled by the cool plate 1006 to a temperature of 100° C. or lower in e.g. about 10-60 seconds. The cooled substrate is sent to the next step.

In this embodiment, a mixed gas of N₂ gas with several % of H₂ gas is used as the antioxidant gas. However, N₂ gas may be used singly.

Though in this embodiment copper is used as an interconnect material, it is also possible to use a copper alloy, silver, a silver alloy, gold, or a gold alloy, or the like, other than copper.

According to the present invention, the use of cobalt phosphinate as a main supply source of cobalt ions and phosphinate ions in the plating bath can avoid the presence of alkali metal ions, such as sodium ions, in the plating bath. This makes it possible to form a protective film selectively on the surfaces of metal interconnects, such as copper interconnects, while preventing contamination of the metal interconnects with an alkali metal. Furthermore, there is no formation of a by-product, such as sodium sulfate, even when the plating bath is continuously used while replenishing the components of the plating bath, making it possible to use the plating bath over a long period of time.

Further, in the case of using the electroless plating bath containing a high-melting metal compound, the high-melting metal is co-deposited and alloyed in the protective film (plated film), whereby the thermal stability of the protective film (plated film) is enhanced.

The present invention will be described in greater detail in the following Examples which do not limit the invention in any manner.

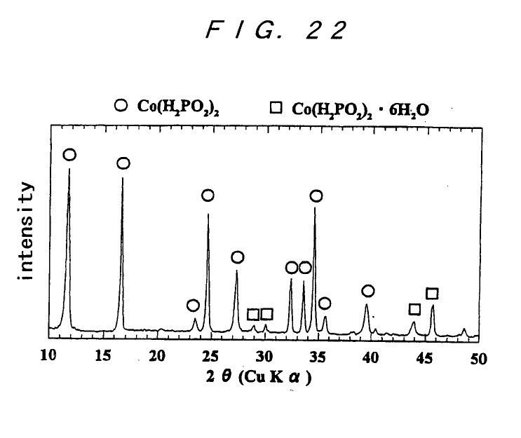

Cobalt phosphinate (Co(H₂PO₂)₂) used in the below -described Examples was prepared by adding cobalt hydroxide (Co(OH)₂) to an aqueous solution of phosphinic acid (H₃PO₂) at a molar ratio of 2:1 of phosphinic acid to cobalt hydroxide and stirring the mixture to dissolve the cobalt hydroxide in the aqueous solution of phosphinic acid, followed by heating of the solution at 60° C. to remove the moisture, and obtain a dry powder. FIG. 22 shows the results of X-ray diffraction analysis of the cobalt phosphinate thus obtained. As can be seen from FIG. 22, the cobalt phosphinate mainly comprises Co(H₂PO₂)₂, with the remainder being its hexahydrate.

### EXAMPLE 1

A silicon wafer having interconnect trenches with a width of 0.5 μm and a depth of 1 μm was provided as a substrate sample for the formation of a fine interconnect circuit. After forming a copper seed layer on the substrate sample in the usual manner, copper plating was carried out to embed copper in the interconnect trenches. Next, the substrate surface was polished by CMP to remove extra copper, thereby preparing an interconnect substrate sample having a copper-interconnects region of embedded copper in the interconnect trenches.

Electroless plating of the thus-obtained interconnect substrate sample was carried out by using electroless plating bath 1, containing cobalt phosphinate and having the composition described below, under the below-described plating conditions to form a plated film (protective film) of a CoP alloy on the surface of the copper-interconnects region. In advance of the electroless plating, the sample was treated with palladium in the usual manner.

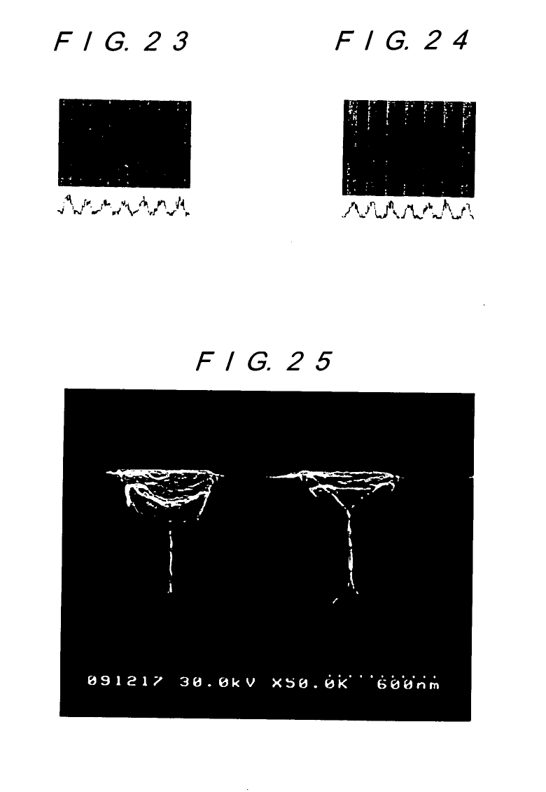

After the plating, observation of the surface morphology of the sample and its elemental analysis by energy dispersive X-ray spectroscopy (EDS) were performed. The results are shown in FIG. 23.

<Composition of electroless plating bath 1>

| Component | Concentration | |
|---|---|---|
| Cobalt phosphinate | 0.1 | mol/L |
| Citric acid | 0.2 | mol/L |
| pH (adjusted with ammonia water) | 8 | |
| <Plating conditions> | | |
| Bath temperature: 90° C. | | |
| Plating time: 60 sec | | |

FIG. 23 clearly shows deposition of the plated film (protective film) of CoP alloy only on the copper-interconnects region, thus indicating good selectivity of plating on the interconnect region.

### EXAMPLE 2

Electroless plating of the same substrate sample was carried out in the same manner as in Example 1, except for using electroless plating bath 2 having the below-described composition instead of the electroless plating bath 1 used in Example 1, under the below-described plating conditions, thereby forming a plated film (protective film) of a CoWP alloy on the surface of the copper-interconnects region.

After the plating, observation of the surface morphology of the sample and its elemental analysis by energy dispersive X-ray spectroscopy (EDS) were performed. The results are shown in FIG. 24.

<Composition of electroless plating bath 2>

| Component | Concentration | |
|---|---|---|
| Cobalt phosphinate | 0.1 | mol/L |
| Citric acid | 0.2 | mol/L |
| Ammonium paratungstate ((NH₄)₁₀W₁₂O₄₁) | 0.005 | mol/L |
| Phosphinic acid | 0.4 | mol/L |
| pH (adjusted with ammonia water) | 10 | |
| <Plating conditions> | | |
| Bath temperature: 90° C. | | |
| Plating time: 60 sec | | |

FIG. 24 clearly shows deposition of the plated film (protective film) of CoWP alloy only on the copper-interconnects region, thus indicating good selectivity of plating on the interconnect region.

### EXAMPLE 3

A 200-mm silicon wafer having interconnect trenches with a width of 0.5 μm and a depth of 1 μm was provided as a substrate sample for the formation of a fine interconnect circuit. A 20 nm-thick barrier layer of TaN was first formed on the substrate sample, and then a 50 nm-thick copper seed layer was formed by sputtering.

Copper plating of the substrate sample having the copper seed layer was carried out in the usual manner to embed copper in the interconnect trenches, followed by CMP to polish the substrate surface and remove extra copper, thereby preparing an interconnect substrate sample having a copper-interconnects region of embedded copper in the interconnect trenches.

Electroless plating of the thus-obtained substrate sample was carried out by using the electroless plating bath 2 used in Example 2 to form a plated film (protective film) of a CoWP alloy. The electroless plating was carried out after subjecting the substrate sample to ultrasonic cleaning with a 50% methanol solution for 5 minutes, immersing the cleaned sample in 10% sulfuric acid at room temperature for one minute, then immersing the sample in a Pd catalyst solution under agitation for 10 seconds, and then again immersing the sample in 10% sulfuric acid at room temperature for one minute.

FIG. 25 is a scanning electron microscope (SEM) photograph of the copper-interconnects region of the substrate sample after plating with the electroless plating bath. FIG. 25 clearly demonstrates the selective formation of the plated film (protective film) of CoWP alloy only on the surfaces of the copper interconnects.

Further, the plated film (protective film) formed was dissolved in a mixed acid of nitric acid and citric acid, and the presence or absence of an alkali metal, such as sodium, was checked by ICP-AES (inductively-coupled plasma atomic emission spectroscopy). As a result, the amount of alkali metal was found to be less than the detection limit.

1. A method for forming a protective film comprising:
providing a substrate having embedded interconnects formed in a surface of the substrate; and
bringing the surface of the substrate into contact with an electroless plating bath, thereby forming a protective film having a film thickness of 0.1 to 500 nm selectively on the exposed surfaces of the embedded interconnects;
wherein the electroless plating bath contains cobalt ions, phosphinate ions and a complexing agent, uses cobalt phosphinate as a main supply source of the cobalt ions and the phosphinate ions, and does not substantially contain alkali metal ions.

2. The method for forming a protective film according to claim 1, wherein the deposition rate of the protective film is 0.1 to 38 nm/min.

3. The method for forming a protective film according to claim 1, wherein the substrate after the formation of the protective film is subjected to heat treatment.

4. The method for forming a protective film according to claim 3, wherein the heat treatment temperature is 120 to 450° C.

5. A method for forming a protective film comprising:
providing a substrate having embedded interconnects formed in a surface of the substrate; and
bringing the surface of the substrate into contact with an electroless plating bath, thereby forming a protective film having a film thickness of 0.1 to 500 nm selectively on the exposed surfaces of the embedded interconnects;
wherein the electroless plating bath contains cobalt ions, phosphinate ions, a complexing agent and a high-melting metal compound, uses cobalt phosphinate as a main supply source of the cobalt ions and the phosphinate ions, and does not substantially contain alkali metal ions.

6. The method for forming a protective film according to claim 5, wherein the high-melting metal contained in the high-melting metal compound is tungsten and/or molybdenum.

7. The method for forming a protective film according to claim 5, wherein the deposition rate of the protective film is 0.1 to 38 nm/min.

8. The method for forming a protective film according to claim 5, wherein the substrate after the formation of the protective film is subjected to heat treatment.

9. The method for forming a protective film according to claim 8, wherein the heat treatment temperature is 120 to 450° C.

10. An electroless plating bath comprising cobalt ions, phosphinate ions and a complexing agent and not substantially containing alkali metal ions, wherein the cobalt ions and the phosphinate ions are mainly derived from cobalt phosphinate obtained by adding cobalt hydroxide to hypophosphorous acid or by the double decomposition reaction between barium hypophosphite and cobalt sulfate.

11. The electroless plating bath according to claim 10 further comprising a high-melting metal compound.

12. The electroless plating bath according to claim 11, wherein the high-melting metal contained in the high-melting metal compound is tungsten and/or molybdenum.

13. The electroless plating bath according to claim 10 not containing sodium ions.
